(19) United States
(12) Patent Application Publication
(10) Pub. No.: US 2025/0273423 A1
(43) Pub. Date: Aug. 28, 2025

(54) ELECTRON GUN AND ELECTRON BEAM WRITING APPARATUS

(71) Applicant: NuFlare Technology, Inc., Yokohama-shi (JP)

(72) Inventors: Mika MIYASAKA, Kawasaki-shi (JP); Nobuo MIYAMOTO, Yokohama-shi (JP)

(73) Assignee: NuFlare Technology, Inc., Yokohama-shi (JP)

(21) Appl. No.: 19/024,642

(22) Filed: Jan. 16, 2025

(30) Foreign Application Priority Data
Feb. 28, 2024 (JP) 2024-028134

(51) Int. Cl. H01J 37/09; H01J 37/063; H01J 37/07; H01J 37/10; H01J 37/317

(52) U.S. Cl. CPC H01J 37/09; H01J 37/063; H01J 37/07; H01J 37/10; H01J 37/3174; H01J 2237/06308

(57) ABSTRACT

An electron gun includes a cathode to emit electron beams, an anode configured to include a surface which faces the cathode and in which there are formed the first opening for passing the electron beams from the cathode and at least one second opening at a position different from that of the first opening and in the same surface as the first opening, and maintained to be a relatively positive potential with respect to a cathode potential, a limiting aperture substrate at the downstream side of the anode with respect to an advancing direction of the electron beams, formed with the third opening for passing the electron beams and limiting passage of a portion of the electron beams, and a Wehnelt electrode between the cathode and the anode, applied with a relatively negative potential with respect to an anode potential.

### CROSS-REFERENCE TO RELATED APPLICATION

This application is based upon and claims the benefit of priority from prior Japanese Patent Application No. 2024-028134 filed on Feb. 28, 2024 in Japan, the entire contents of which are incorporated herein by reference.

### BACKGROUND OF THE INVENTION

### Field of the Invention

Embodiments of the present invention relate to an electron gun and an electron beam writing apparatus, and, for example, to an electron source installed in a multiple beam writing apparatus.

### Description of Related Art

The lithography technique which advances miniaturization of semiconductor devices is extremely important as a unique process whereby patterns are formed in semiconductor manufacturing. In recent years, with high integration of LSI, the line width (critical dimension) necessary for semiconductor device circuits is becoming increasingly narrower year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple-beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In the electron gun which emits electron beams, after the electron beams pass through the anode, secondary electrons or reflected electrons are generated due to that a part of the electron beams collides with an aperture substrate, resulting in generation of cations (or “positive ions”) from gas molecules in the atmosphere. Then, if the cations flow backwards (reversely) and collide with the surface of the cathode (emitter), crystals may be damaged, which poses a problem of incapable of securing electron beams with a sufficient current distribution. It becomes necessary to exchange the cathode from which electron beams having a sufficient current distribution are not emitted/acquired.

With regard to an electron gun mounted in an X-ray device, there is disclosed a technique which forms a plurality of exhaust paths in the side surface of a tubular electron passage hole arranged at the cathode side from the anode electrode surface in order to decrease the pressure in the electron passage hole through the exhaust paths, thereby reducing generation of cations (e.g., refer to Japanese Patent Application Laid-open (JP-A) No. 2012-256441). However, this poses a problem when a tubular member of a positive potential with respect to the cathode exists at the cathode side from the anode electrode surface, the risk of electric discharge increases.

### BRIEF SUMMARY OF THE INVENTION

According to one aspect of the present invention, an electron gun includes
a cathode configured to emit an electron beam;
an anode electrode configured to include a surface which faces the cathode, and in which there are formed a first opening for passing the electron beam emitted from the cathode, and at least one second opening at a position different from a position of the first opening, the at least one second opening being formed in a same surface as the first opening, and maintained at a relatively positive potential with respect to a potential of the cathode;
a limiting aperture substrate arranged at a downstream side of the anode electrode with respect to an advancing direction of the electron beam, configured to be formed with a third opening for passing the electron beam, and limit passage of a portion of the electron beam; and
a Wehnelt electrode arranged between the cathode and the anode electrode, configured to be applied with a relatively negative potential with respect to a potential of the anode electrode.

According to another aspect of the present invention, an electron beam writing apparatus includes
a stage configured to mount thereon a target object;
an electron gun configured to include
   a cathode which emits an electron beam,
   an anode electrode configured to include a surface which faces the cathode, and in which there are formed a first opening for passing the electron beam emitted from the cathode, and at least one second opening at a position different from a position of the first opening, the at least one second opening being formed in a same surface as the first opening, and maintained at a relatively positive potential with respect to a potential of the cathode,
   a limiting aperture substrate arranged at a downstream side of the anode electrode with respect to an advancing direction of the electron beam, configured to be formed with a third opening for passing the electron beam, and limit passage of a portion of the electron beam, and
   a Wehnelt electrode arranged between the cathode and the anode electrode, configured to be applied with a relatively negative potential with respect to a potential of the anode electrode; and
an electron optical system configured to lead the electron beam emitted from the electron gun to the target object.

### BRIEF DESCRIPTION OF THE DRAWINGS

FIG. 1 is an illustration showing a schematic configuration diagram of a writing apparatus according to a first embodiment;

FIG. 2 is an illustration showing an example of a circuit configuration of an electron gun and a high-voltage power supply circuit according to the first embodiment;

FIG. 3 is a top view showing an example of a configuration of an anode electrode according to the first embodiment;

FIG. 4 is an illustration showing an example of an internal configuration of an electron gun according to a comparative example of the first embodiment;

FIG. 5 is an illustration showing an example of an internal configuration of an electron gun according to the first embodiment;

FIG. 6 is an illustration showing an example of a result of a simulation where cations flow backwards according to a comparative example of the first embodiment;

FIG. 7 is an illustration showing an example of a result of a simulation where cations flow backwards in the case of forming an opening at a position away from an electron beam passage hole by a distance y1 according to the first embodiment;

FIG. 8 is an illustration showing an example of a result of a simulation where cations flow backwards in the case of forming an opening at a position away from an electron beam passage hole by a distance y2 according to the first embodiment;

FIG. 9 is an illustration showing an example of a result of a simulation where cations flow backwards in the case of forming an opening at a position away from an electron beam passage hole by a distance y3 according to the first embodiment;

FIG. 10 is an illustration showing an example of a result of a simulation where cations flow backwards in the case of forming an opening with a diameter size D21;

FIG. 11 is an illustration showing an example of a result of a simulation where cations flow backwards in the case of forming an opening with a diameter size D22;

FIG. 12 is an illustration showing an example of a result of a simulation where cations flow backwards in the case of forming an opening with a diameter size D23;

FIG. 13 is an illustration showing a positional relationship in an electron gun according to the first embodiment;

FIG. 14 is a graph showing an example of a relationship between an optimal distance from a passage hole of an anode to an opening and a distance between the anode and a Wehnelt according to the first embodiment;

FIG. 15 is a table showing an example of a relationship between an optimal distance from a passage hole of an anode to an opening and a distance between the anode and a Wehnelt according to the first embodiment;

FIG. 16 is an illustration showing an example of an internal configuration of an electron gun according to a modified example 1 of the first embodiment;

FIG. 17 is an illustration showing an example of an internal configuration of an electron gun according to a modified example 2 of the first embodiment;

FIG. 18 is an illustration showing another example of a return portion at the anode backside according to the modified example 2 of the first embodiment;

FIG. 19 is a conceptual diagram showing a configuration of a shaping aperture array substrate according to the first embodiment;

FIG. 20 is a sectional view showing a configuration of a blanking aperture array mechanism according to the first embodiment;

FIG. 21 is a conceptual diagram showing an example of writing operations according to the first embodiment;

FIG. 22 is an illustration showing an example of an irradiation region of multiple beams and a writing target pixel according to the first embodiment; and

FIG. 23 is an illustration explaining an example of a multi-beam writing operation according to the first embodiment.

### DETAILED DESCRIPTION OF THE INVENTION

Embodiments of the present invention provide an apparatus capable of preventing that cations (or “positive ions”) generated due to collision of electrons having passed through the opening of the anode electrode flow backwards (reversely) to the cathode.

Embodiments of the present invention describe a configuration which uses multiple electron beams. However, the electron beam is not limited to multiple beams, and a single beam may also be used.

### First Embodiment

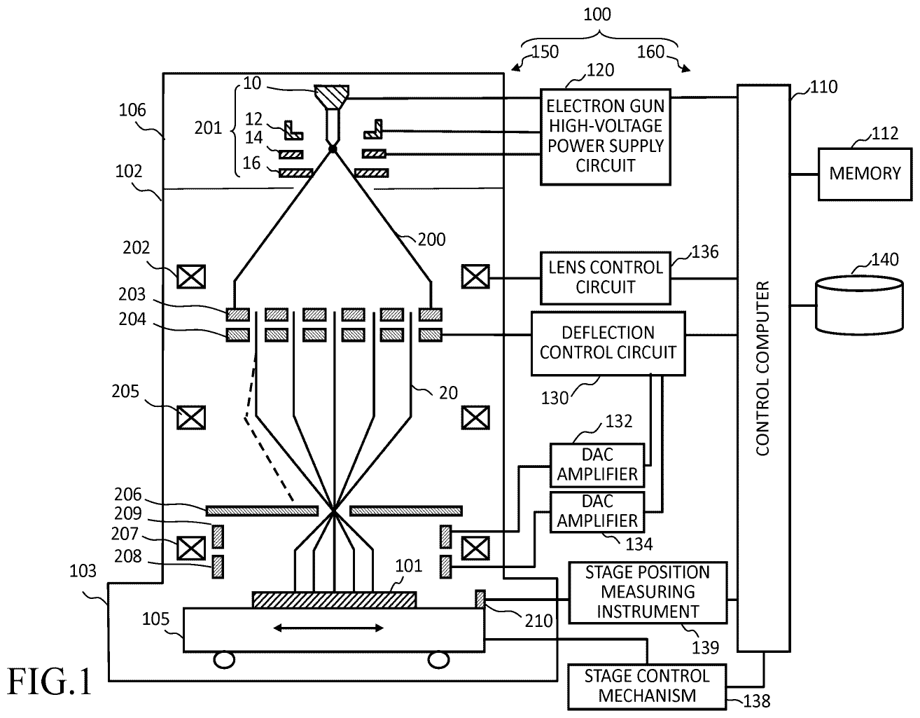

FIG. 1 is an illustration showing a schematic configuration diagram of a writing or “drawing” apparatus according to a first embodiment. As shown in FIG. 1, a writing apparatus 100 includes a writing mechanism 150 and a control system circuit 160. The writing apparatus 100 is an example of a multiple electron beam writing apparatus, and a multiple electron beam exposure apparatus. The writing mechanism 150 includes an electron gun chamber 106, an electron optical column 102 (electron beam column) and a writing chamber 103. The electron gun chamber 106 is disposed above the electron optical column 102. The electron optical column 102 is disposed above the writing chamber 103.

In the electron gun chamber 106, there is disposed an electron gun 201. In the electron optical column 102, there is arranged an electron optical system, such as an illumination lens 202, a shaping aperture array substrate 203, a blanking aperture array mechanism 204, a reducing lens 205, a limiting aperture substrate 206, an objective lens 207, a main deflector 208, and a sub deflector 209.

In the writing chamber 103, an XY stage 105 is disposed. On the XY stage 105, there is placed a target object or “sample” 101 such as a mask serving as a writing target substrate when writing (exposure) is performed. The target object 101 is, for example, an exposure mask used in fabricating semiconductor devices, or a semiconductor substrate (silicon wafer) for fabricating semiconductor devices. Furthermore, the target object 101 may be, for example, a mask blank on which resist has been applied and nothing has yet been written. On the XY stage 105, a mirror 210 for measuring the position of the XY stage 105 is placed.

The control system circuit 160 includes a control computer 110, a memory 112, a high-voltage power supply circuit 120, a deflection control circuit 130, digital-analog converter (DAC) amplifier units 132 and 134, a lens control circuit 136, a stage control mechanism 138, a stage position measuring instrument 139, and a storage device 140 such as a magnetic disk drive. The control computer 110, the memory 112, the high-voltage power supply circuit 120, the deflection control circuit 130, the lens control circuit 136, the stage control mechanism 138, the stage position measuring instrument 139, and the storage device 140 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier unit 132 disposed for each electrode. The main deflector 208 is composed of at least four electrodes (or “at least four poles”), and controlled by the deflection control circuit 130 through the DAC amplifier unit 134 disposed for each electrode. Lenses such as the illumination lens 202, the reducing lens 205, and the objective lens 207 are controlled by the lens control circuit 136. The electron gun 201 is controlled by the high-voltage power supply circuit 120.

The high-voltage power supply circuit 120, the deflection control circuit 130, the lens control circuit 136, the stage control mechanism 138, and the stage position measuring instrument 139 are controlled by the control computer 110. Information input to the control computer 110 and information calculated in the control computer 110 are stored in the memory 112.

Chip data (writing data) on a chip including a plurality of figure patterns is input to the writing apparatus 100 from its outside, and stored in the storage device 140. Chip data defines information on a plurality of figure patterns configuring a chip pattern. Specifically, for example, coordinates for each vertex are defined for each figure pattern in the order of configuration of the figure. Alternatively, for example, a figure code, coordinates, a size, and the like are defined for each figure pattern.

The control computer 110 reads the writing data from the storage device 140, performs multi-stage data processing, and controls, in accordance with the writing sequence, the high-voltage power supply circuit 120, the deflection control circuit 130, the lens control circuit 136, the stage control mechanism 138, and the stage position measuring instrument 139.

Each of the illumination lens 202, the reducing lens 205, and the objective lens 207 is configured by an electromagnetic lens, and a reduction optical system is configured by the reducing lens 205 and the objective lens 207. The illumination lens 202 functions as a collimating lens.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

The electron gun 201 includes a thermionic emission type cathode 10, a Wehnelt 12 (Wehnelt electrode), an anode 14 (anode electrode), and a limiting aperture substrate 16. The Wehnelt 12 is arranged between the cathode 10 and the anode 14. The limiting aperture substrate 16 is arranged at the downstream side of the anode 14 with respect to the advancing direction of an electron beam 200. Since the Wehnelt 12 and the anode 14 function as electrodes, it goes without saying that they are made from conductive material.

FIG. 1 shows configuration elements necessary for describing the first embodiment. Other configuration elements generally necessary for the writing apparatus 100 may also be included therein.

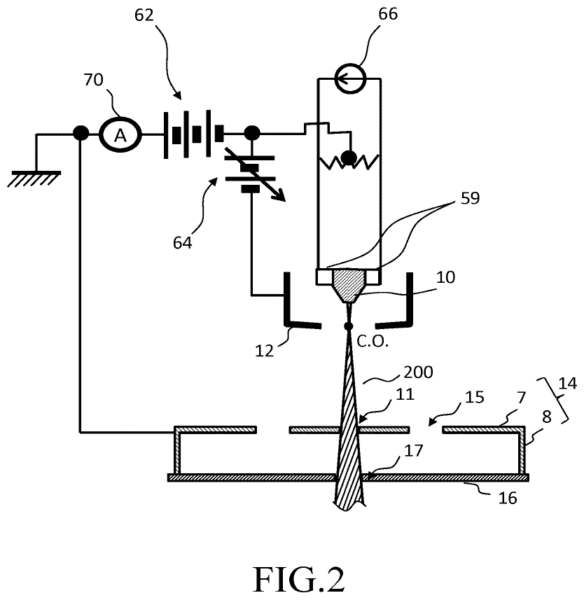

FIG. 2 is an illustration showing an example of a circuit configuration of an electron gun and a high-voltage power supply circuit according to the first embodiment. In FIG. 2, a passage hole 11 (first opening) through which the electron beam 200 emitted from the cathode 10 passes is formed in the anode 14. The anode 14 is grounded, and its electric potential is set to be a ground (GND) potential. In other words, the anode 14 is maintained at a relatively positive side potential with respect to the potential of the electron beam 200. The high-voltage power supply circuit 120 is connected to the electron gun 201. The high-voltage power supply circuit 120 applies an acceleration voltage between the cathode 10 and the anode 14. As the acceleration voltage, a potential negative with respect to a ground potential applied to the anode 14 is applied to the cathode 10. The high-voltage power supply circuit 120 applies a negative bias voltage to the Wehnelt 12. In other words, the Wehnelt 12 is arranged between the cathode 10 and the anode 14, and is applied with a relatively negative side potential with respect to the potential of the anode 14. It will be specifically described.

In the high-voltage power supply circuit 120, there are disposed an acceleration voltage power supply 62, a Wehnelt power supply 64, and a heater power supply 66. The cathode (−) side of the acceleration voltage power supply 62 is connected to the cathode 10 through a heater 59 in the electron gun 201. The anode (+) side of the acceleration voltage power supply 62 is connected to the anode 14 (anode electrode) in the electron gun 201, and to the ground. An ammeter 70 is connected in series between the anode (+) of the acceleration voltage power supply 62 and the anode 14. The cathode (−) of the acceleration voltage power supply 62 is branched to be connected to the anode (+) of the Wehnelt power supply 64. The cathode (−) of the Wehnelt power supply 64 is connected to the Wehnelt 12 (Wehnelt electrode) disposed between the cathode 10 and the anode 14. The heater power supply 66 is connected to the heater 59.

At the time of emission of electron beams, after the arrangement atmosphere in the electron gun 201 is maintained to be in a vacuum state of a predetermined pressure by a vacuum pump (not shown), if the cathode 10 is heated by the heater 59 in a state where a fixed negative Wehnelt voltage (bias voltage) is applied to the Wehnelt 12 from the Wehnelt power supply 64 and a fixed negative acceleration voltage is applied to the cathode 10 from the acceleration voltage power supply 62, electron beams (electrons) are emitted from the cathode 10, and the emitted electron beams (electrons) are accelerated, by an acceleration voltage, to travel toward the anode 14.

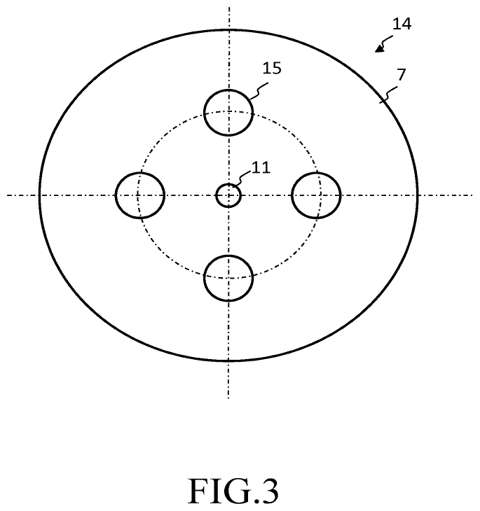

FIG. 3 is a top view showing an example of a configuration of an anode electrode according to the first embodiment. In the examples of FIGS. 2 and 3, the anode 14 includes, for example, a disc electrode substrate 7. The surface of the electrode substrate 7 is facing the cathode 10. In other words, the anode 14 includes a surface opposite to the cathode 10, and the passage hole 11 (first opening) through which the electron beam 200 emitted from the cathode 10 passes is formed in this surface. The passage hole 11 is preferably formed at the center of the electrode substrate 7. In the anode 14, at least one opening 15 (second opening) is formed, at a position different from that of the passage hole 11, in the same surface where the passage hole 11 is formed. For example, at least one opening 15 (second opening) larger than the passage hole 11 is formed.

Furthermore, as shown in FIGS. 2 and 3, as the at least one passage hole 15, it is preferable that a plurality of passage holes 15 are formed to be rotationally symmetric about the center of the passage hole 11.

The electron beam 200 having passed through the passage hole 11 of the anode 14 travels toward the limiting aperture substrate 16. A passage hole 17 (third opening) through which the electron beam 200 passes is formed in the limiting aperture substrate 16, and passage of a portion of the electron beam 200 is limited. For example, a beam spreading wider than a desired radiation angle is blocked. Furthermore, scattered electrons, etc. are blocked.

In the case of FIG. 2, the anode 14 includes a supporting cylinder 8 extending to the downstream side with respect to the advancing direction of the electron beam 200 from the outer peripheral part of the electrode substrate 7. The anode 14 is supported above the limiting aperture substrate 16 through the supporting cylinder 8. Preferably, the limiting aperture substrate 16 is made from conductive material. In that case, a ground potential is applied to the limiting aperture substrate 16 through the anode 14.

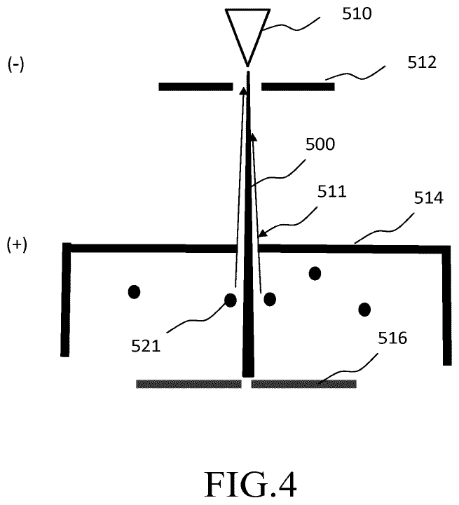

FIG. 4 is an illustration showing an example of an internal configuration of an electron gun according to a comparative example of the first embodiment.

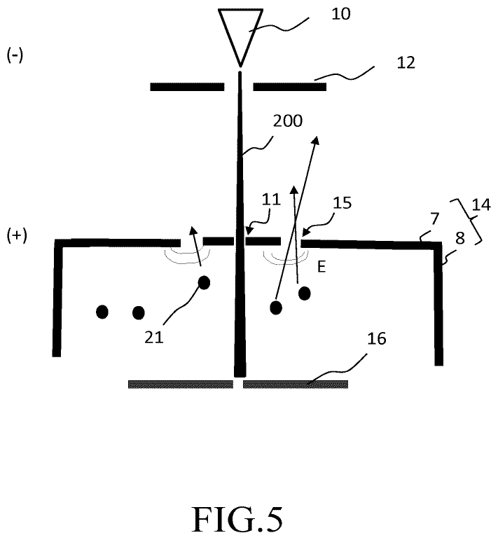

FIG. 5 is an illustration showing an example of an internal configuration of an electron gun according to the first embodiment.

In FIG. 4, an electron beam 500 emitted from a cathode 510 is accelerated by an acceleration voltage and a bias voltage applied to a Wehnelt 512, and passes through a passage hole 511 of an anode 514. Then, it travels to a limiting aperture substrate 516. In FIG. 4, a crossover formed in the vicinity of the Wehnelt 512 is not shown. The same applies to each following figure. In FIG. 4, a portion of the electron beam 500 having passed through the anode 514 collides with the limiting aperture substrate 516 to emit a secondary electron or a reflected electron. Generally, by performing baking treatment to the electron gun chamber, gas generation from the chamber is promoted, the inside is highly vacuumized, and the number of gas molecules being ion seeds is reduced as small as possible. However, a secondary electron or a reflected electron collides with a gas molecule remaining without being exhausted, thereby generating a cation 521. The cation 521 generated under the anode 514 is attracted by space charge, passes through the passage hole 511, and then, collides with the cathode 510 along the electron beam 500. Thereby, crystals configuring the cathode 510 are damaged to locally form a hollow. This poses a problem of incapable of acquiring a sufficient current distribution. If damaged, the cathode 510 needs to be exchanged.

Also, in the first embodiment shown in FIG. 5, similarly to the comparative example, the electron beam 200 emitted from the cathode 10 is accelerated by an acceleration voltage and a bias voltage applied to the Wehnelt 12, and passes through the passage hole 11 of the anode 14. Then, it travels to the limiting aperture substrate 16. A portion of the electron beam 200 having passed through the anode 14 collides with the limiting aperture substrate 16 to emit a secondary electron or a reflected electron. Therefore, also in the first embodiment, similarly to the comparative example, by performing baking treatment to the electron gun chamber 106, gas generation from the chamber is promoted, a secondary electron or a reflected electron collides with a gas molecule remaining without being exhausted, thereby generating a cation 21. However, according to the first embodiment, as shown in FIG. 5, at least one opening 15 having a different size from the passage hole 11 is formed in the vicinity of the passage hole 11 of the anode 14. For example, at least one opening 15 larger than the passage hole 11 is formed. Although the opening 15 is desirably circular, for example, it is not limited thereto. Any shape is acceptable as long as a larger area than the area of the passage hole 11 is obtained. For example, the opening 15 may be an ellipse or a rectangle. Alternatively, it may be an arc, for example.

Since the opening 15 is larger in size than the passage hole 11, the conductance increases as the area of the opening increases, and the probability of passage of cations also increases. For this reason, it is possible to let many cations 21 go into the electron gun chamber 106 outside the anode 14 from the opening 15 formed on a different position from the electron beam trajectory.

As shown in FIG. 5, the cathode 10 and Wehnelt 12 are maintained at a relatively negative potential with respect to the anode 14, and the anode 14 is maintained at a relatively positive potential. Therefore, an electric field is generated between them. Then, by forming the opening 15 in the surface opposite to the cathode 10, an electric field E leaks also in the opening 15. Thereby, the cation 21 is drawn by the electric field E. If the size of the opening 15 is smaller than the passage hole 11, the cation 21 is drawn by the passage hole 11. According to the first embodiment, since the size of the opening 15 is larger than the passage hole 11, in addition to the improvement of the conductance described above, more cations 21 can be drawn by the opening 15 due to the pulling effect of the electric field. For this reason, it is possible to let more cations 21 go into the electron gun chamber 106 outside the anode 14 from the opening 15 formed on a different position from the electron beam trajectory. Thus, the number of cations which collide with the cathode 10 through the passage hole 11 can be suppressed or reduced. In the case of making the size of the opening 15 equal to or smaller than the passage hole 11, it is preferable to form a plurality of openings 15 and make the total area of the openings larger than the passage hole 11.

Furthermore, according to the first embodiment, since the electrode substrate 7 of the anode 14 is arranged to face the cathode 10 and no equipotential structure is arranged on the electrode substrate 7, the risk of electric discharge can be avoided or reduced.

Furthermore, as shown in FIG. 3, by arranging a plurality of openings 15 to be rotationally symmetric (even arrangement), deviation of distribution of emitted cations is hard to occur, and the cations 21 can be efficiently emitted from the backside surface of the anode 14.

Next, optimization of the opening 15 is escribed.

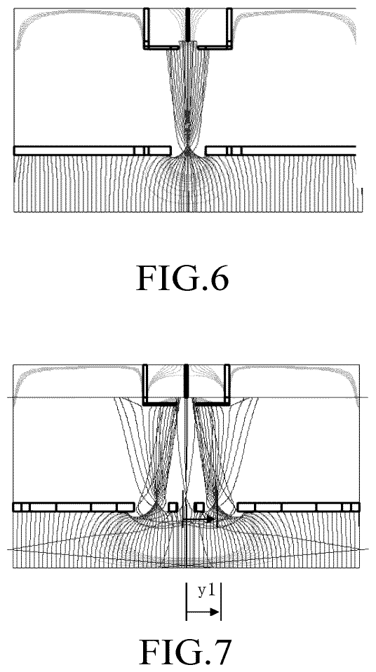

FIG. 6 is an illustration showing an example of a result of a simulation where cations flow backwards according to a comparative example of the first embodiment.

FIG. 7 is an illustration showing an example of a result of a simulation where cations flow backwards in the case of forming an opening at a position away from the electron beam passage hole by a distance y1 according to the first embodiment.

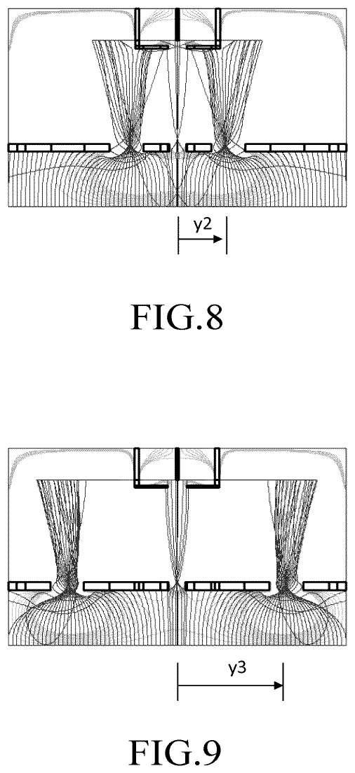

FIG. 8 is an illustration showing an example of a result of a simulation where cations flow backwards in the case of forming an opening at a position away from the electron beam passage hole by a distance y2 according to the first embodiment.

FIG. 9 is an illustration showing an example of a result of a simulation where cations flow backwards in the case of forming an opening at a position away from the electron beam passage hole by a distance y3 according to the first embodiment.

In FIGS. 7 to 9, the relation is y3>y2>y1, and y1=3 mm, y2=5 mm, and y3=10 mm, for example. Furthermore, each of FIGS. 7 to 9 shows the distance of 15 mm between the anode and the Wehnelt, for example. In the comparative example, as shown in FIG. 6, many cations flow backwards toward the cathode from the electron beam passage hole. In contrast, it turns out that, by forming the opening 15 at the position away by the distance y1, the emission amount of cations from the opening 15 is increased and the emission amount of cations from the electron beam passage hole is decreased. Moreover, it turns out that, by forming the opening 15 at the position away by the distance y2, the emission amount of cations from the opening 15 is further increased and the emission amount of cations from the electron beam passage hole is further decreased. However, in the case of forming the opening 15 at the position away by the distance y3, it turns out that the emission amount of cations from the opening 15 is less than the case of the distance y2, but the emission amount of cations from the electron beam passage hole 11 increases more than the cases of the distances y1 and y2 although the emission amount of cations from the electron beam passage hole is less than the comparative example. Thus, it turns out there exists an optimal solution for the distance from the electron beam passage hole 11 to the opening 15.

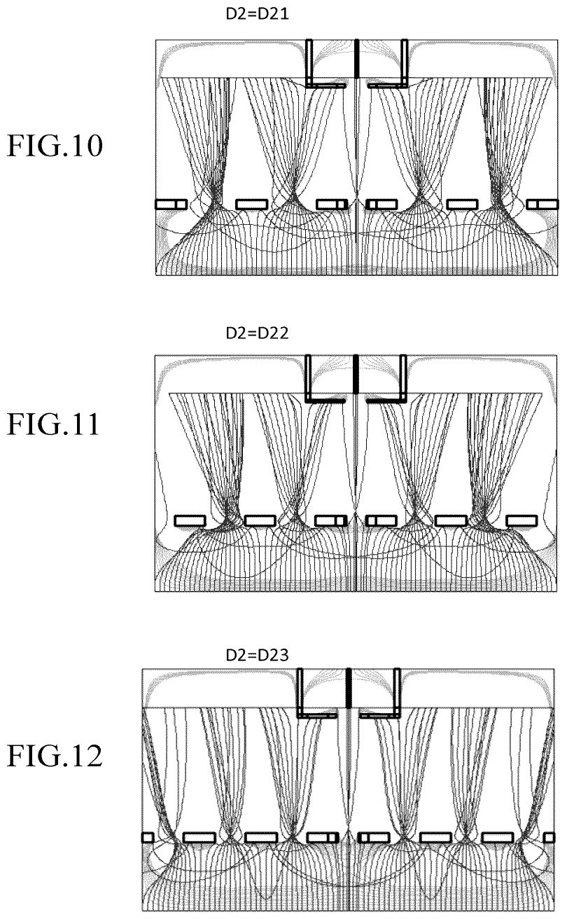

FIG. 10 is an illustration showing an example of a result of a simulation where cations flow backwards in the case of forming an opening with a diameter size D21.

FIG. 11 is an illustration showing an example of a result of a simulation where cations flow backwards in the case of forming an opening with a diameter size D22.

FIG. 12 is an illustration showing an example of a result of a simulation where cations flow backwards in the case of forming an opening with a diameter size D23.

In FIGS. 10 to 12, the relation is D21<D22<D23. Each diameter size is larger than the electron beam passage hole 11. FIG. 10 shows the case where the diameter size D21 is larger by 1 mm than the diameter size D1 of the electron beam passage hole 11. FIG. 11 shows the case where the diameter size D22 is larger by 2 mm than the diameter size D1 of the electron beam passage hole 11. FIG. 12 shows the case where the diameter size D23 is larger by 3 mm than the diameter size D1 of the electron beam passage hole 11. As shown in the examples of FIGS. 10 to 12, it turns out that the influence of the change of the diameter size of the opening 15 on the emission amount of cations from the electron beam passage hole 11 is small.

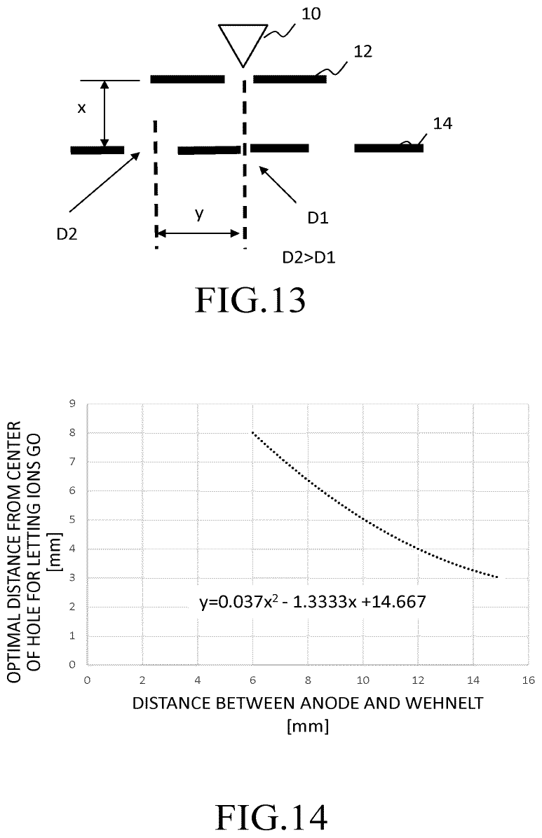

FIG. 13 is an illustration showing a positional relationship in an electron gun according to the first embodiment. In FIG. 13, there are shown the distance x between the Wehnelt 12 and the anode 14, and the distance y from the passage hole 11 of the anode 14 to the opening 15. The distance y indicates the distance between the centers. Furthermore, in FIG. 13, there are shown the diameter size D1 of the electron beam passage hole 11, and the diameter size D2 of the opening 15.

FIG. 14 is a graph showing an example of a relationship between an optimal distance from a passage hole of the anode to an opening and a distance between the anode and the Wehnelt according to the first embodiment. The diameter of the passage hole 11 of the anode is 2 mm. In FIG. 14, the ordinate axis represents the distance y from the passage hole 11 of the anode 14 to the opening 15, and the abscissa axis represents the distance x between the anode and the Wehnelt. As shown in FIG. 14, the optimal distance y from the center of the passage hole 11 to the center of the opening 15 satisfies a quadratic equation which uses, as a parameter, the distance x between the anode 14 and the Wehnelt 12. Specifically, the optimal distance y from the center of the passage hole 11 to the center of the opening 15 satisfies the following equation (1) using, as a parameter, the distance x between the anode 14 and the Wehnelt 12.

$$y = 0.037 {x}^{2} - 1.333 x + 14.667 \qquad ( 1 )$$

When the distance x between the anode and the Wehnelt is 15 mm, as shown in FIGS. 7 and 8, with respect to the cases where the distance y is 3 mm and the distance y2 is 5 mm, there is no large effect difference between the both cases. In addition, although not shown, in the case of the distance y being 1 mm, since the emission amount of cations from the electron beam passage hole 11 is large, no good effect is acquired. Based on these results, it turns out that the margin of 2 mm is permissible with regard to the distance y. In other words, +1 mm margin for the optimum value of the distance y can be allowed. Therefore, it is preferable for the distance y from the center of the passage hole 11 to the center of the opening 15 to satisfy the following equation (2) which uses, as a parameter, the distance x between the anode 14 and the Wehnelt 12. mm is used as the unit of both the distances x and y.

$$y = 0.037 {x}^{2} - 1.333 x + 14.667 \pm 1.000 \qquad ( 2 )$$

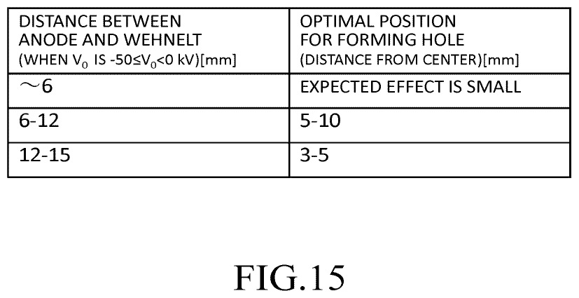

FIG. 15 is a table showing an example of a relationship between an optimal distance from a passage hole of the anode to an opening and a distance between the anode and the Wehnelt according to the first embodiment. FIG. 15 shows a result in the case where the acceleration voltage V0 between the cathode 10 and the anode 14 is −50 kV<=V0<0. In FIG. 15, based on the result of the graph of FIG. 14, when the distance between the anode and the Wehnelt is 6 to 12 mm, the optimal distance from the passage hole 11 of the anode 14 to the opening 15 is 5 to 10 mm. When the distance between the anode and the Wehnelt is 12 to 15 mm, the optimal distance from the passage hole 11 of the anode 14 to the opening 15 is 3 to 5 mm. If the distance between the anode and the Wehnelt is less than 6 mm, since that distance is too short, the electric field at the central part becomes strong, and therefore, it turns out that the effect of letting cations go out from the opening 15 is small. Even when the acceleration voltage V0 is greater than −50 kV on the negative side, the relationship in FIG. 15 is satisfied.

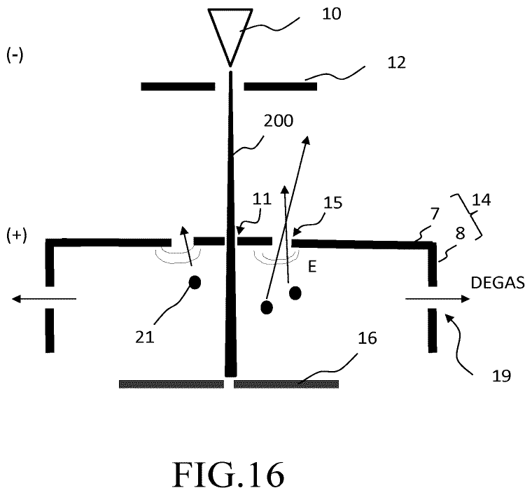

FIG. 16 is an illustration showing an example of an internal configuration of an electron gun according to a modified example 1 of the first embodiment. The modified example 1 of the first embodiment shown in FIG. 16 is the same as FIG. 5 except that at least one opening 17 is formed in the side surface of the supporting cylinder 8 of the anode 14. By forming at least one opening 17 in the side surface of the supporting cylinder 8, the exhaust efficiency of gas generated in the supporting cylinder 8 can be increased when performing exhausting by a vacuum pump (not shown). Consequently, the number of emitted cations 21 itself can be reduced. With regard to at least one opening 17, it is preferable to evenly arrange a plurality of openings 17.

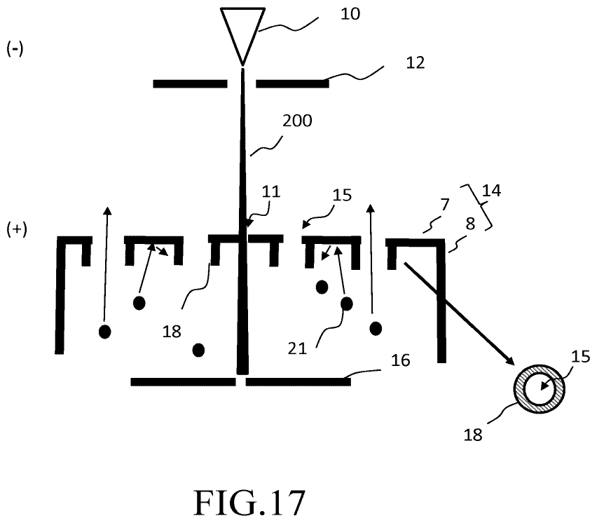

FIG. 17 is an illustration showing an example of an internal configuration of an electron gun according to a modified example 2 of the first embodiment. The modified example 2 shown in FIG. 17 is the same as FIG. 5 except that a return portion 18 (convex portion) is further formed to be extended from the backside of the surface, which faces the cathode 10, of the anode 14 toward the limiting aperture substrate 16. The return portion 18 is arranged in the vicinity of the outer periphery of at least one opening 15. FIG. 17 shows the case where the return portion 18 is tubularly (cylindrically) arranged along the outer periphery of the opening 15. By arranging the return portion 18 at each opening 15, it becomes easy to temporarily confine the cations 21 in a space surrounded by the backside of the electrode substrate 7, the internal side surface of the supporting cylinder 8, and the limiting aperture substrate 16. By this, the number of collision times of a cation colliding with the backside of the electrode substrate 7 and the internal side surface of the supporting cylinder 8 can be increased. Thereby, the energy of the cation 21 can be attenuated. Thereby, if, even when the cation 21 flows backwards from the electron beam passage hole 11 to the cathode 10, the influence on the crystal serving as the cathode 10 can be reduced. Although, due to the arrangement of the return portion 18, it becomes difficult for the cation 21 to pass through the opening 15, cations whose number is larger than that of cations passing through the electron beam passage hole 11 can be emitted from the opening 15. If the length L of the return portion 18 is too long, it becomes difficult for the cations 21 to be emitted/discharged through the opening 15. Therefore, preferably, the length L of the return portion 18 is equal to or less than the diameter size D2 of the opening 15.

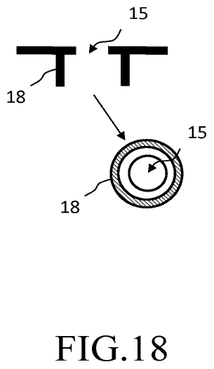

FIG. 18 is an illustration showing another example of the return portion at the anode backside according to the modified example 2 of the first embodiment. FIG. 18 shows the case where the tubular (cylindrical) return portion 18 whose diameter size is larger than the outer periphery of the opening 15 is arranged surrounding the opening 15. Thus, there is no necessity of making the arrangement position of the return portion 18 coincide with the outer periphery of the opening 15.

Although, in the examples described above, each return portion 18 is arranged to surround the whole circumference of one of the openings 15, it is not limited thereto. A part of the circumference of the opening 15 may not be enclosed by the return portion 18. Alternatively, the return portion 18 may be arranged at only a part of the openings 15 without being arranged at all the openings 15.

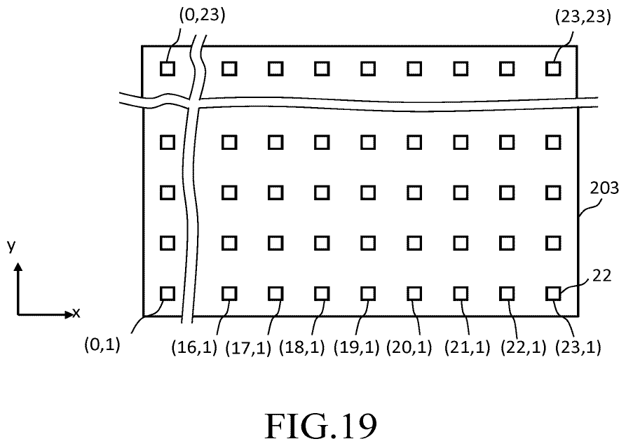

FIG. 19 is a conceptual diagram showing a configuration of a shaping aperture array substrate according to the first embodiment. As shown in FIG. 19, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 19, for example, holes (openings) 22 of 24×24, that is 24 holes in the y direction and 24 holes in the x direction, are formed. The number of holes 22 is not limited thereto. For example, it is also preferable to form the holes 22 of 512×512. Each of the holes 22 is a rectangle (including square) having the same dimension and shape as each other. Alternatively, each of the holes 22 may be a circle with the same diameter as each other. Multiple beams 20 are formed by letting portions of the electron beam 200 individually pass through a corresponding one of a plurality of holes 22. In other words, the shaping aperture array substrate 203 forms the multiple beams 20.

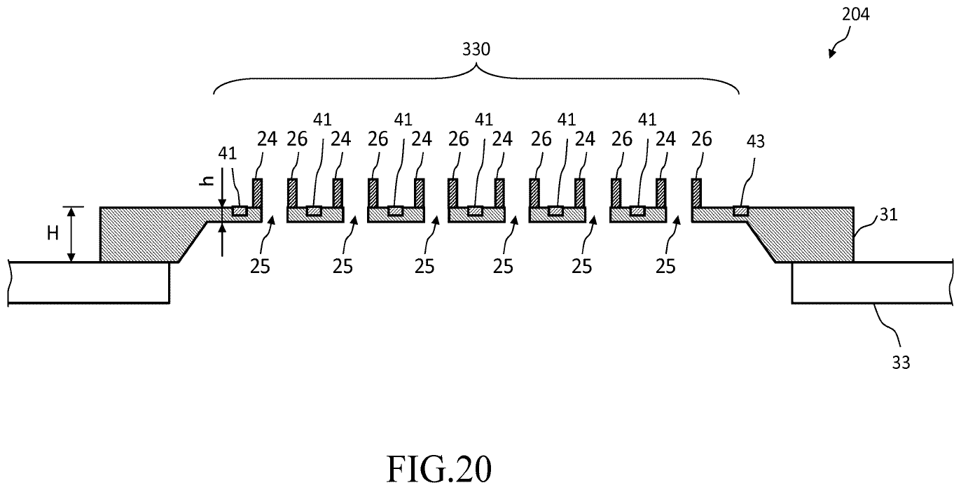

FIG. 20 is a sectional view showing a configuration of a blanking aperture array mechanism according to the first embodiment. In the blanking aperture array mechanism 204, as shown in FIG. 20, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 19. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. Electron beams emitted from the electron gun 201 are led to the target object 101 by the electron optical system. Specifically, it operates as follows: The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. Then, the electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in the OFF state by the blanker of the blanking aperture array mechanism 204. Then, each beam for one shot of the multiple beams 20 is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at the pitch obtained by multiplying the arrangement pitch of a plurality of holes 22 in the shaping aperture array substrate 203 by the desired reduction ratio described above.

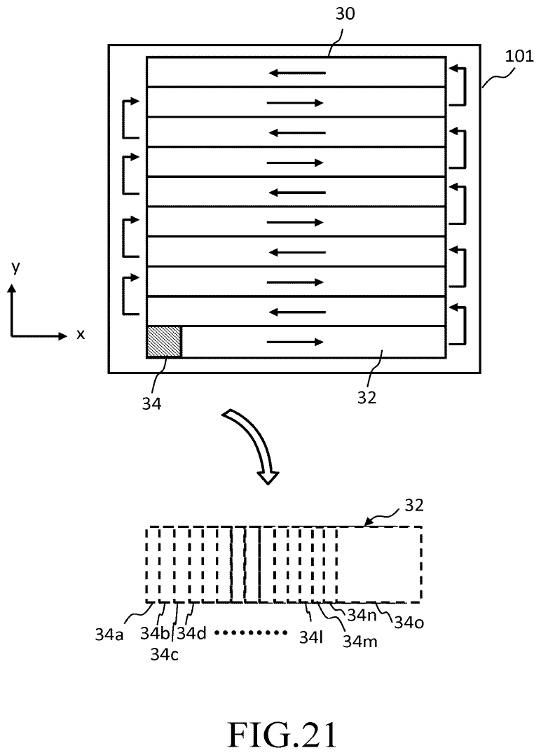

FIG. 21 is a conceptual diagram showing an example of writing operations according to the first embodiment. As shown in FIG. 21, a writing region 30 (bold line) of the target object 101 is virtually divided into a plurality of stripe regions 32 by a predetermined width in the y direction, for example. In the case of FIG. 21, the writing region 30 of the target object 101 is divided in the y direction, for example, into a plurality of stripe regions 32 by the width size being substantially the same as the design size of an irradiation region 34 (writing field) which can be irradiated by one irradiation with the multiple beams 20. Now, an example of the writing operation will be described.

First, the XY stage 105 is moved to make an adjustment such that the irradiation region 34 of the multiple beams 20 is located at the left end, or at a position further left than the left end, of the first stripe region 32. Then, when performing writing to the first stripe region 32, the XY stage 105 is moved, for example, in the −x direction, so that the writing may relatively proceed in the x direction. The XY stage 105 is moved, for example, continuously at a constant speed.

After writing to the first stripe region 32, the stage position is moved in the −y direction by the width size of the stripe region 32. Thereby, the stripe region 32 to be written is shifted (displaced) in the y direction by the width size of the stripe region 32.

Next, an adjustment is made so that the irradiation region 34 of the multiple beams 20 can be located at the right end, or at a position further right than the right end, of the second stripe region 32. By moving the XY stage 105, for example, in the +x direction, the writing relatively proceeds in the −x direction. Thereby, writing is performed to the second stripe region 32. Henceforth, by repeating similar operations, writing to all the stripe regions 32 is performed.

Thus, due to performing writing while alternately changing the writing direction, the stage moving time can be reduced, which results in reducing the writing time. Owing to one shot of multiple beams having been formed by individually passing through the holes 22 in the shaping aperture array substrate 203, a plurality of shot patterns maximally up to as many as the number of the holes 22 are formed at a time.

In the case of FIG. 21, each stripe region 32 is written in order while alternately changing the writing direction, but the writing operation is not limited to this. It is also preferable to perform writing in the same direction when writing each stripe region 32.

Although, in the case of FIG. 21, writing is performed to each pixel once, it is not limited thereto. Multiple writing which performs writing a plurality of times to each pixel is also acceptable by making the XY stage 105 pass each stripe region a plurality of times. In that case, it is also preferable to shift the position of the stripe region according to the number of times of multiple writing. Furthermore, it is also preferable to perform multiple writing by writing the same pixel a plurality of times during one movement of the stage.

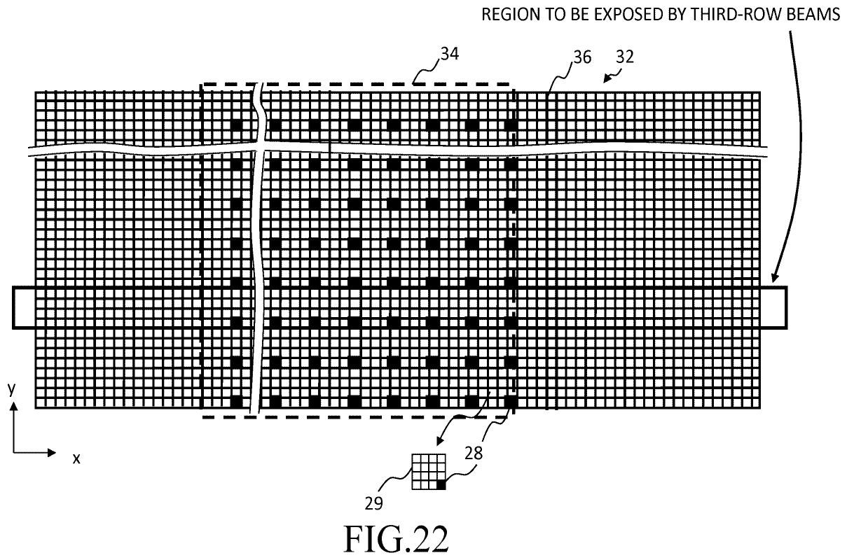

FIG. 22 is an illustration showing an example of an irradiation region of multiple beams and a pixel to be written (writing target pixel) according to the first embodiment. In FIG. 22, the stripe region 32 is divided into a plurality of mesh regions by the beam size of the multiple beams 20, for example. Each mesh region serves as a writing target pixel 36 (beam irradiation unit region, irradiation position). The size of the writing target pixel 36 is not limited to the beam size, and may be any size regardless of beam size. For example, it may be 1/n (n being an integer of 1 or more) of the beam size. FIG. 22 shows the case where the writing region of the target object 101 is divided, for example, in the y direction, into a plurality of stripe regions 32 by the width size being substantially the same as the size of the irradiation region 34 (writing field) which can be irradiated by one irradiation of the multiple beams 20. The x-direction size of the rectangular, including square, irradiation region 34 can be defined by (the number of x-direction beams)×(beam pitch in the x direction). The y-direction size of the rectangular irradiation region 34 can be defined by (the number of y-direction beams)×(beam pitch in the y direction). FIG. 22 shows the case of multiple beams of 24×24 (rows×columns) being simplified to 8×8 (rows×columns). In the irradiation region 34, there are shown a plurality of pixels 28 (beam writing positions) which can be irradiated with one shot of the multiple beams 20. The pitch between adjacent pixels 28 is the beam pitch of the multiple beams. A sub-irradiation region 29 (pitch cell region) is configured by a rectangular, including square, region surrounded by the size of beam pitches in the x and y directions. In the example of FIG. 22, each sub-irradiation region 29 is composed of 4×4 pixels, for example.

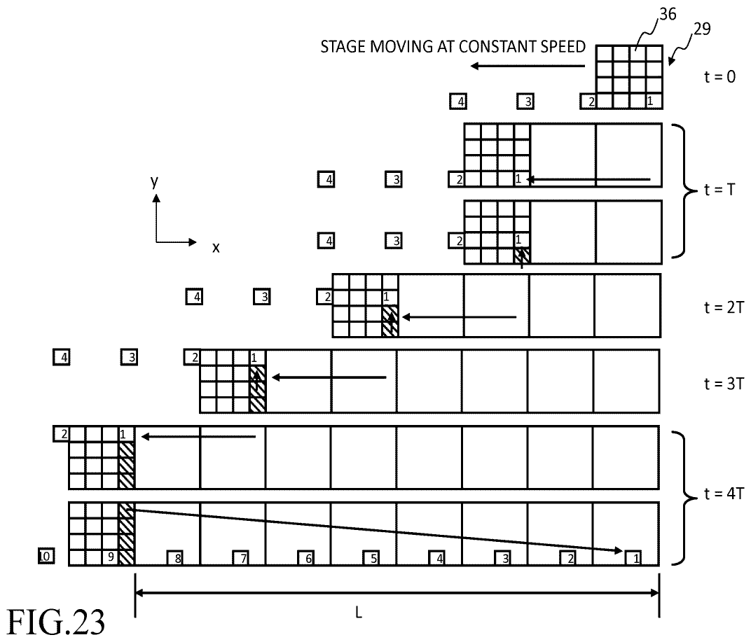

FIG. 23 is an illustration explaining an example of a multi-beam writing operation according to the first embodiment. FIG. 23 shows the case where the inside of each sub-irradiation region 29 is written with four different beams. Furthermore, the example of FIG. 23 shows a writing operation where the XY stage 105 continuously moves at the speed at which the XY stage 105 moves the distance L of eight beam pitches while a ¼ region, namely the region of 1/(the number of beams used for irradiation), in each sub-irradiation region 29 is written. In the writing operation shown in FIG. 23, for example, while the XY stage 105 moves the distance L of eight beam pitches, different four pixels in the same sub-irradiation region 29 are written (exposed) by being applied with four shots of the multiple beams 20 at a shot cycle T with shifting the irradiation position (pixel 36) in order by the sub deflector 209. In order that the relative position between the irradiation region 34 and the target object 101 may not be shifted by the movement of the XY stage 105 while these four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking starting position. Since writing of the pixels in the first column from the right of each sub-irradiation region 29 has been completed, in the next tracking cycle after resetting the tracking, first, the sub deflector 209 provides deflection such that the beam writing position is adjusted (shifted) to write the second pixel column from the right still not having been written in each sub-irradiation region 29, for example. By repeating this operation during writing the stripe region 32, as shown in the lower part of FIG. 21, the position of the irradiation region 34 of the multiple beams 20 is sequentially moved (shifted), such as the irradiation region 34a, 34b, 34c, . . . 34o, to perform writing.

As described above, according to the first embodiment, it is possible to prevent or reduce the backward flowing of the cations 21 generated due to collision of electrons having passed through the passage hole 11 of the anode 14 to the cathode 10.

Embodiments have been explained referring to specific examples described above. However, the present invention is not limited to these specific examples.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any electron gun and electron beam writing apparatus that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electron gun comprising:
a cathode configured to emit an electron beam;
an anode electrode configured to include a surface which faces the cathode, and in which there are formed a first opening for passing the electron beam emitted from the cathode, and at least one second opening at a position different from a position of the first opening, the at least one second opening being formed in a same surface as the first opening, and maintained at a relatively positive potential with respect to a potential of the cathode;
a limiting aperture substrate arranged at a downstream side of the anode electrode with respect to an advancing direction of the electron beam, configured to be formed with a third opening for passing the electron beam, and limit passage of a portion of the electron beam; and
a Wehnelt electrode arranged between the cathode and the anode electrode, configured to be applied with a relatively negative potential with respect to a potential of the anode electrode.

2. The electron gun according to claim 1, wherein the at least one second opening is larger in size than the first opening.

3. The electron gun according to claim 1, wherein a distance from a center of the first opening to a center of the at least one second opening satisfies a quadratic equation which uses, as a parameter, a distance between the anode electrode and the Wehnelt electrode.

4. The electron gun according to claim 1, wherein a distance y from a center of the first opening to a center of the at least one second opening satisfies an equation of y=0.037x²−1.333x+14.667±1.000 which uses, as a parameter, a distance x between the anode electrode and the Wehnelt electrode.

5. The electron gun according to claim 1, wherein, as the at least one second opening, a plurality of second openings are formed to be rotationally symmetric about a center of the first opening.

6. The electron gun according to claim 1, further comprising:
a convex portion formed to be extended from a backside of the surface of the anode electrode toward the limiting aperture substrate, and arranged in a vicinity of an outer periphery of each second opening of the at least one second opening.

7. The electron gun according to claim 6, wherein the convex portion is formed to be tubular along the outer periphery of the each second opening.

8. The electron gun according to claim 1, wherein the anode electrode includes a supporting cylinder extending from an outer peripheral part of the anode electrode toward the limiting aperture substrate.

9. An electron beam writing apparatus comprising:
a stage configured to mount thereon a target object;
an electron gun configured to include
a cathode which emits an electron beam,
an anode electrode configured to include a surface which faces the cathode, and in which there are formed a first opening for passing the electron beam emitted from the cathode, and at least one second opening at a position different from a position of the first opening, the at least one second opening being formed in a same surface as the first opening, and maintained at a relatively positive potential with respect to a potential of the cathode,
a limiting aperture substrate arranged at a downstream side of the anode electrode with respect to an advancing direction of the electron beam, configured to be formed with a third opening for passing the electron beam, and limit passage of a portion of the electron beam, and
a Wehnelt electrode arranged between the cathode and the anode electrode, configured to be applied with a relatively negative potential with respect to a potential of the anode electrode; and
an electron optical system configured to lead the electron beam emitted from the electron gun to the target object.

10. The electron beam writing apparatus according to claim 9, wherein the at least one second opening is larger in size than the first opening.
